(19) United States
(12) Patent Application Publication
(10) Pub. No.: US 2025/0176212 A1
(43) Pub. Date: May 29, 2025

(54) Trench Gate Semiconductor Device and Method for Manufacturing the Same

(71) Applicant: Hangzhou Silicon-Magic Semiconductor Technology Co.,Ltd, Hangzhou (CN)

(72) Inventor: Yu SUN, Hangzhou (CN)

(73) Assignee: Hangzhou Silicon-Magic Semiconductor Technology Co., Ltd, Hangzhou (CN)

(21) Appl. No.: 18/946,945

(22) Filed: Nov. 14, 2024

(30) Foreign Application Priority Data
Nov. 24, 2023 (CN) 2023115869038

(51) Int. Cl. H01L 29/78; H01L 29/08; H01L 29/10; H01L 29/423; H01L 29/66

(52) U.S. Cl. CPC H10D 30/668; H10D 30/0297; H10D 62/155; H10D 62/393; H10D 64/513

(57) ABSTRACT

A trench gate semiconductor device having a substrate, an epitaxial layer, at least one first trench gate structure and at least one second trench gate structure. The epitaxial layer is formed on the substrate. The at least one first trench gate structure and the at least one second trench gate structure are formed in the epitaxial layer. The at least one first trench gate structure has a first depth. The at least one second trench gate structure has a second depth. The first depth is greater than the second depth. The at least one first trench gate structure and the at least one second trench gate structure are arranged alternately in a line along a first direction, and the neighboring first trench gate structure and second trench gate structure adjoins each other.

### CROSS-REFERENCE TO RELATED APPLICATION

This application claims the benefit of Chinese Patent Application No. 202311586903.8, filed on Nov. 24, 2023, which is incorporated herein by reference in its entirety.

### TECHNICAL FIELD

The present disclosure relates to semiconductor devices and in particular to structure of trench gate semiconductor devices and the method for manufacturing the same.

### BACKGROUND

Trench gate semiconductor devices include trench gate MOSFET (Metal Oxide Semiconductor Field Effect Transistor), SGT (Shielded Gate Trench) MOSFET, trench gate IGBT (Insulated Gate Bipolar Transistor), SJ (Super Junction) MOSFET, etc. Compared with the conventional semiconductor devices, the trench gate semiconductor devices have lower on resistance and higher switching speed, and are widely applied in industrial, automotive, consumer electronics and energy systems.

In the trench gate semiconductor devices, current channels are formed alongside the sidewalls of the trench gates. However, as the device size continues to decrease, the current density of the device is approaching the limit.

### SUMMARY

In order to solve the technical problem in the prior art, the present disclosure provides a trench gate semiconductor device with optimized trench gate structure to improve the current density of the semiconductor device. Meanwhile, a method for manufacturing the trench gate semiconductor device is provided.

The embodiments of the present invention are directed to a trench gate semiconductor device includes a substrate, an epitaxial layer, at least one first trench gate structure and at least one second trench gate structure. The substrate has a first surface and a second surface parallel and opposite to the first surface. The epitaxial layer is formed on the first surface of the substrate. The epitaxial layer has a first surface and a second surface parallel and opposite to the first surface of the epitaxial layer. The at least one first trench gate structure and the at least one second trench gate structure are formed in the epitaxial layer. The at least one first trench gate structure vertically extends from the first surface of the epitaxial layer, and has a first depth. The at least one second trench gate structure vertically extends from the first surface of the epitaxial layer, and has a second depth. The first depth is greater than the second depth. The at least one first trench gate structure and the at least one second trench gate structure are arranged alternately in a line along a first direction, and the neighboring first trench gate structure and second trench gate structure adjoins each other.

The embodiments of the present invention are directed to a trench gate semiconductor device includes a substrate, an epitaxial layer, a first trench gate structure and a second trench gate structure. The substrate has a first surface and a second surface parallel and opposite to the first surface. The epitaxial layer is formed on the first surface of the substrate. The epitaxial layer has a first surface and a second surface parallel and opposite to the first surface of the epitaxial layer. The first trench gate structure and the second trench gate structure are formed in the epitaxial layer. The first trench gate structure vertically extends from the first surface of the epitaxial layer, and has a first depth. The second trench gate structure vertically extends from the first surface of the epitaxial layer, and has a second depth. The first depth is greater than the second depth. The first trench gate structure and the second trench gate structure are arranged in a line along a first direction and adjoins each other.

The embodiments of the present invention are directed to a manufacturing method of a trench gate semiconductor device. The manufacturing method includes forming a substrate having a first surface and a second surface parallel and opposite to the first surface; forming an epitaxial layer on the first surface of the substrate having a first surface and a second surface parallel and opposite to the first surface of the epitaxial layer; forming a body region in the epitaxial layer; forming at least one first trench gate structure and at least one second trench gate structure in the body region; forming a source region in the body region, wherein the source region has a sidewall adjoins the at least one first trench gate structure and the at least one second trench gate structure along a first direction. The at least one first trench gate structure and the at least one second trench gate structure are arranged alternately in a line along the first direction and are connected to each other. The at least one first trench gate structure has a first depth and the at least one second trench gate structure has a second depth. The first depth is greater than the second depth and a depth of the body region.

### BRIEF DESCRIPTION OF FIGURES

The present disclosure can be further understood with reference to following detailed description and appended drawings, wherein like elements are provided with like reference numerals. These drawings are only for illustration purpose, thus may only show part of the devices and are not necessarily drawn to scale. It is obvious that the drawings described below are some implementations of the present disclosure, and those skilled in the art would also obtain other drawings on the basis of these drawings, without involving any inventive skill.

FIG. 1a shows structure of a transistor cell of a conventional semiconductor device 10.

FIG. 1b shows the structure of the transistor cell of semiconductor device 10 in FIG. 1a cutting along line A-A.

FIG. 2a schematically shows a trench gate semiconductor device 20 in accordance with an embodiment of the present disclosure.

FIG. 2b schematically shows a cross-sectional view the trench gate semiconductor device 20 in FIG. 2a cutting along line B-B in accordance with an embodiment of the present disclosure.

FIG. 2c shows a dissembled view of the half transistor cell in FIG. 2b in accordance with an embodiment of the present disclosure.

FIGS. 3a-3f schematically show the trench gate semiconductor device 20 at different stages of the manufacturing process in accordance with an embodiment of the present disclosure.

The use of the same reference label in different drawings indicates the same or like components.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, well-known structures, materials, processes or operations are not shown or described in detail to avoid obscuring aspects of the present disclosure.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

Unless specifically noted below, portions of the semiconductor device may include materials well known to those skilled in the art. Semiconductor materials include, for example, III-V group semiconductors such as gallium arsenide (GaAs), gallium nitride (GaN), and the like, IV-IV group semiconductors such as silicon carbide (SIC), and the like, II-VI compound semiconductors such as cadmium sulfide (CdS), cadmium telluride (CdTe), and the like, and IV group semiconductors such as silicon (Si), germanium (Ge), and the like. The gate electrode may consist of or contain, as main constituent(s), aluminum (AI), copper (Cu), or alloys of aluminum or copper, for example AlSi, AlCu or AlSiCu. According to other embodiments, at least one of the gate electrodes may contain, as main constituents(s), nickel (Ni), tin (Sn), titanium (Ti), tungsten (W), tantalum (Ts), vanadium (V), silver (Ag), gold (Au), platinum (Pt), and/or palladium (Pd). For example, at least one of the gate load electrodes may include two or more sub-layers, wherein each sub-layer contains one or more of Ni, Sn, Ti, V, Ag, Au, Pt, W, and Pd as main constituent(s), e.g., a silicide, a nitride and/or an alloy. The gate dielectric may include SiO₂. The gate dielectric may include or may consist of a semiconductor oxide, or a material having a dielectric constant greater than SiO₂, including, for example, oxides, nitrides, nitrogen oxides, silicates, aluminates, titanates. Moreover, the gate dielectric may include not only materials known to those skilled in the art, but also materials developed in the future for use of insulation.

The present disclosure may be used with but not limited to trench gate MOSFET (Metal Oxide Semiconductor Field Effect Transistor), SGT (Shielded Gate Trench) MOSFET, trench gate IGBT (Insulated Gate Bipolar Transistor), SJ (Super Junction) MOSFET, etc. Embodiments of trench gate MOSFETs below are provided for illustrating the spirit of the present disclosure.

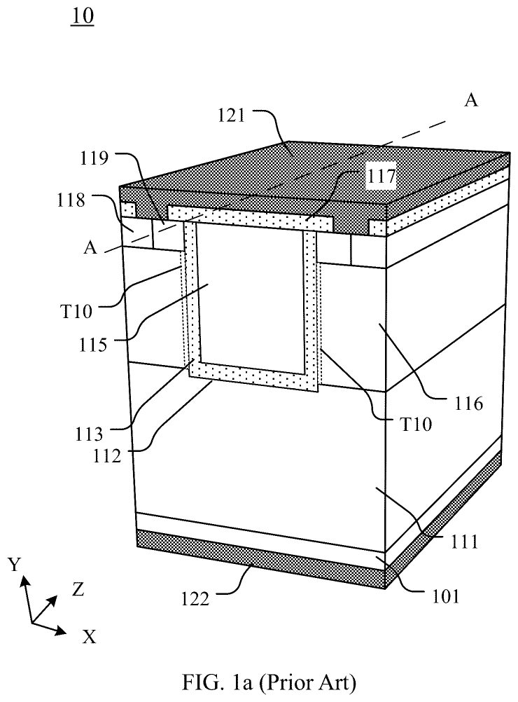

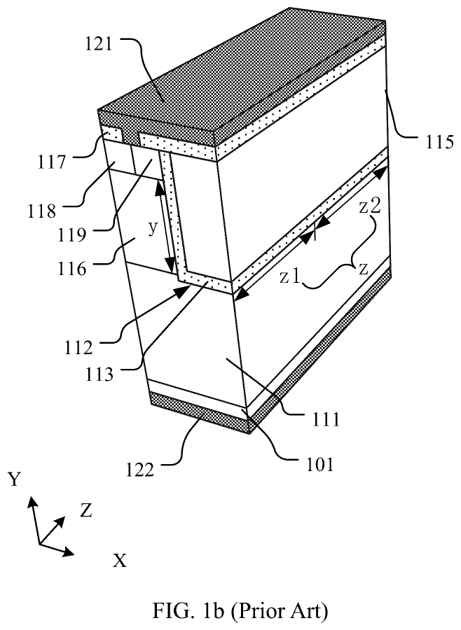

FIG. 1a shows structure of a transistor cell of a conventional semiconductor device 10. FIG. 1b shows the structure of the transistor cell of semiconductor device 10 in FIG. 1a cutting along line A-A. As shown in FIGS. 1a and 1b, the semiconductor device 10 includes a substrate 101 having a first surface and an opposite second surface, an epitaxial layer 111 on the first surface of the substrate 101, a trench 112 formed in the epitaxial layer 111, a gate dielectric layer 113 and a gate electrode 115 formed in the trench 112, a body region 116 formed in the epitaxial layer 111 and adjoining the trench 112, a source region 119 formed in the body region 116 and adjoining the trench 112, a contact region 118 formed in the body region 116 and adjoining the source region 119, an interlayer dielectric layer 117 on the epitaxial layer 111, a source electrode 121 contacting the contact region 118 and source region 119 via openings of the interlayer dielectric layer 117, and a drain electrode 122 contacting the second surface of the substrate 101.

The trench 112 extends vertically from a first surface of epitaxial layer 111 into the interior along a Y-axial as shown in FIGS. 1a and 1b. When the trench gate semiconductor device 10 is on, the portion of the body region 116 alongside the sidewalls of the trench 112, i.e., regions T10 as shown in FIG. 1a, are inverted. In one embodiment, the length of the trench 112 along a first direction (along the Z-axial as shown in FIGS. 1a and 1b) is assumed as z, the length of the portion of the trench 112 along a depth direction (along the Y-axial as shown in FIGS. 1a and 1b) is assumed as y. When the semiconductor device 10 is on, surface areas of the inverted regions T10 alongside the trench 112 are provided as: S=2*y*z.

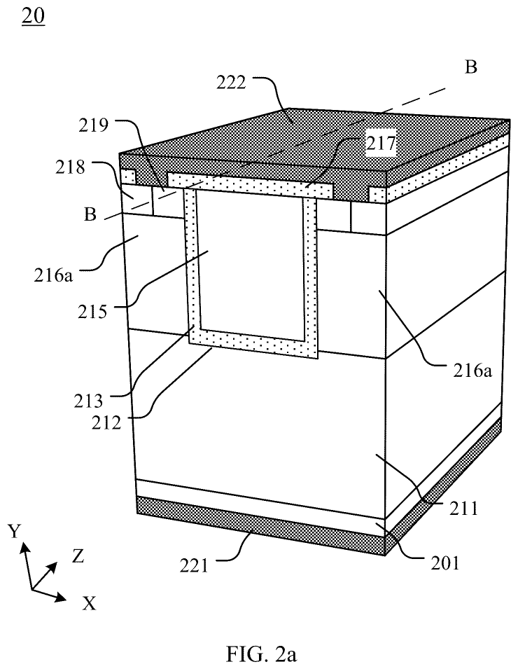

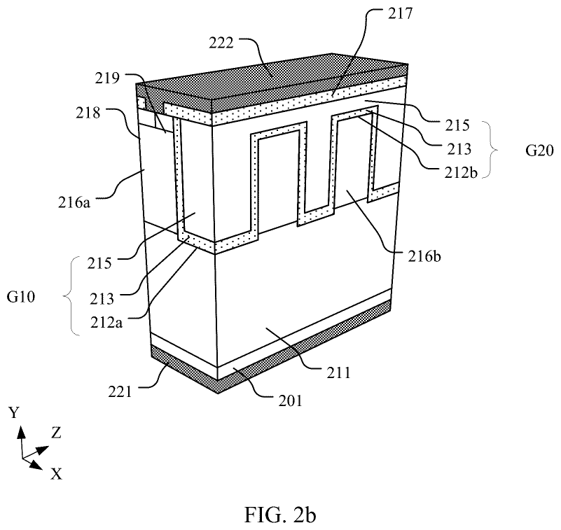

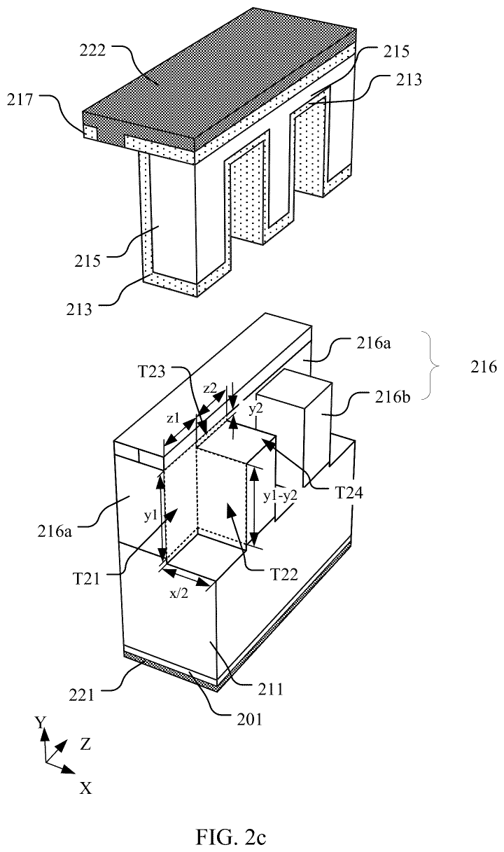

FIG. 2a schematically shows a trench gate semiconductor device 20 in accordance with an embodiment of the present disclosure. FIG. 2b schematically shows a cross-sectional view of the trench gate semiconductor device 20 in FIG. 2a cutting along line B-B in accordance with an embodiment of the present disclosure. For clear illustration, one transistor cell of the trench gate semiconductor device 20 is shown in FIG. 2a. It should be understood that the trench gate semiconductor device 20 includes a plurality of transistor cells. The line B-B is along the X-axis, and is in the middle of the transistor cell. That is to say, FIG. 2b shows half of the transistor cell. FIG. 2c shows a dissembled view of the half transistor cell in FIG. 2b in accordance with an embodiment of the present disclosure.

In the embodiments of the present disclosure, the first conductivity type is n-type and the second conductivity type is p-type. Similar considerations as outlined below apply to embodiments with the first conductivity type being p-type and the second conductivity type being n-type. By implanting n-type dopants, like P or As, into a semiconductor layer, n-type layer could be formed. By implanting p-type dopants, like B, into a semiconductor layer, p-type layer could be formed.

As shown in FIGS. 2a-2c, the transistor cell of the trench gate semiconductor device 20 includes a substrate 201 and an epitaxial layer 211. The substrate 201 is configured as a drain region of the trench gate semiconductor device 20. The substrate 201 has a first surface and a second surface parallel and opposite to the first surface. The epitaxial layer 211 is on the first surface of the substrate 201. The epitaxial layer 211 is configured as a drift region of the trench gate semiconductor device 20. In one embodiment, both of the substrate 201 and the epitaxial layer 211 have the first conductivity type. In one embodiment, the substrate 201 is n-type with high doping level, and the epitaxial layer 211 has a relatively lower doping level.

As shown in FIG. 2a, the transistor cell of the trench gate semiconductor device 20 includes trenches 212 formed in the epitaxial layer 211. As shown in FIG. 2b, the trenches 212 includes first trenches 212a and second trenches 212b. The first trenches 212a and the second trenches 212b vertically extend from a first surface of the epitaxial layer 211 to the interior. The first trenches 212a and the second trenches 212b are alternately arranged along a first direction, i.e., the Z-axial direction as shown in FIGS. 2a-2c. The alternating first trenches 212a and the second trenches 212b adjoin each other. The first trench 212a and the second trench 212b have different depth along Y-axial. In the embodiment of FIG. 2b, the first trench 212a has a greater depth than the second trench 212b.

The trench gate semiconductor device 20 includes a gate dielectric layer 213 and a gate electrode 215. The gate dielectric layer 213 covers an inner surface of the first trenches 212a and the second trenches 212b. The gate electrode 215 fills in the cavity formed by the first trenches 212a and the second trenches 212b, with the gate dielectric layer 213 in between for insulation. Each first trench 212a, the portion of the gate dielectric layer 213 covering the inner surface of the corresponding first trench 212a, and the portion of the gate electrode 215 filling in the corresponding first trench 212a form a first trench gate structure G10. Each second trench 212b, the portion of the gate dielectric layer 213 covering the inner surface of the corresponding second trench 212b, and the portion of the gate electrode 215 filling in the corresponding second trench 212b form a second trench gate structure G20. The first trench gate structure G10 and the second trench gate structure G20 have different depths along the Y-axial. In one embodiment, the depth of the first trench gate structure G10 is greater than the depth of the second trench gate structure G20.

The trench gate semiconductor device 20 includes a body region 216 having the second conductivity type. The body region 216 includes first portions 216a and second portions 216b. The first portions 216a and the second portions 216b are connected and form an integrity. In a second direction, i.e., the X-axial direction, the first portions 216a are arranged along both sides of the alternating first trench gate structures G10 and second trench gate structures G20. In other words, the first portions 216a along the opposite sides sandwich and adjoin the first trench gate structure G10 and the second trench gate structure G20. The second portions 216b are arranged between the neighboring first trench gate structures G10, and are under the second trench gate structures G20. Each second portion 216b of the body region 216 adjoins the neighboring first trench gate structures G10 and the bottom wall of the associated second trench gate structure G20. In the first direction, the first trench gate structures G10 and the second portions 216b of the body region 216 are arranged alternately, and adjoin each other.

The trench gate semiconductor device 20 includes the source region 219, the contact region 218 and the interlayer dielectric layer 217. The source region 219 has the first conductivity type and is formed in the body region 216, specifically, in the first portions 216a of the body region 216. The contact region may have the second conductivity type, and is formed in the body region 216, specifically, in the first portions 216a of the body region 216. The interlayer dielectric layer 217 covers the contact region 218, the source region 219 and the gate electrode 215. The source region 219 has a smaller depth than the second trench gate structure G20 in a third direction, i.e., along the Y-axial.

The trench gate semiconductor device 20 includes a drain electrode 221 and a source electrode 222. The drain electrode 221 covers the second surface of the substrate 201, and electrically connects the substrate 201. The source electrode 222 is atop the interlayer dielectric layer 217, and contacts and electrically connects the contact region 218 and the source region 219 through conductive medias, like vias, in the openings of the interlayer dielectric layer 217.

In the embodiment in FIG. 2c of the present disclosure, a surface of the first portion 216a of the body region 216 which adjoins the sidewall of the first trench gate structure G10 is assumed as a surface T21. A surface of the second portion 216b of the body region 216 which contacts the other sidewall (normal to the Z-axial) of the first trench gate structure G10 is assumed as a surface T22. A surface of the first portion 216a of the body region 216 which contacts a sidewall of the second trench gate structure G20 is assumed as a surface T23. A surface of the second portion 216b of the body region 216 which contacts a bottom wall of the second trench gate structure G20 is assumed as a surface T24.

When the trench gate semiconductor device 20 is on, the surfaces T21, T22, T23 and T24 are inverted. In one embodiment, in a depth direction, along the Y-axial, the surface T21 has a length y1, and the surface T23 has a length y2. Consequently, the surface T22 has a length y1−y2 along the Y-axial (the thickness of the gate dielectric layer 213 is small and omitted). In the first direction along the Z-axial, the first trench gate structure G10 has a length z1, and the second trench gate structure G20 has a length z2. In the second direction along the X-axial, both of the first trench gate structure G10 and the second trench gate structure G20 have a length x. Accordingly, the surface T21 has an area S21=y1*z1, the surface T22 has an area S22=(y1−y2)*x/2, the surface T23 has an area S23=y2*z2, and the surface T24 has an area S24=z2*x/2.

When the trench gate semiconductor device 20 is on, the total inverted area S1 of the body region 216 in a single transistor cell having one first trench gate structure G10 and one second trench gate structure G20 could be found from:

$$S 1 = 2 * S 21 + 4 * S 22 + 2 * S 23 + 2 * S 24 = 2 * y 1 * z 1 + 2 * ( y 1 - y 2 ) * x + 2 * y 2 * z 2 + z 2 * x \qquad ( 1 )$$

The total inverted area S of the body region 116 in a single transistor cell of the conventional semiconductor device is: S=2*y*z.

In the conventional trench gate semiconductor device 10, the length z of trench 112 in the first direction along the Z-axial is assumed as: z=z1+z2. Assuming the length y of the inverted area of the body region 116 that adjoins the trench 112 in the depth direction along the Y-axial is: y=y1. If S1−S>0, from equation (1), it could be found that:

$$S = 2 * S 21 + 4 * S 22 + 2 * S 23 + 2 * S 24 = 2 * y 1 * z 1 + 2 * ( y 1 - y 2 ) * x + 2 * y 2 * z 2 + x * z 2 - 2 * y * ( z 1 + z 2 ) > 0 .$$

From the above equation, the length range of z2, i.e., the length range of the second trench gate structure G20 in the first direction, which makes S1>S, could be found by:

$$0 < z 2 < \frac{2 * ( y 1 - y 2 ) * x}{2 * ( y 1 - y 2 ) - x} \qquad ( 2 )$$

It indicates that as long as the length of the second trench 212b in the first direction is in the range defined by the above equation (2), the power density and the resistance of the trench gate semiconductor device could be improved. In other words, the power density and the resistance of the trench gate semiconductor device could be improved by configuring gate trenches with different depths.

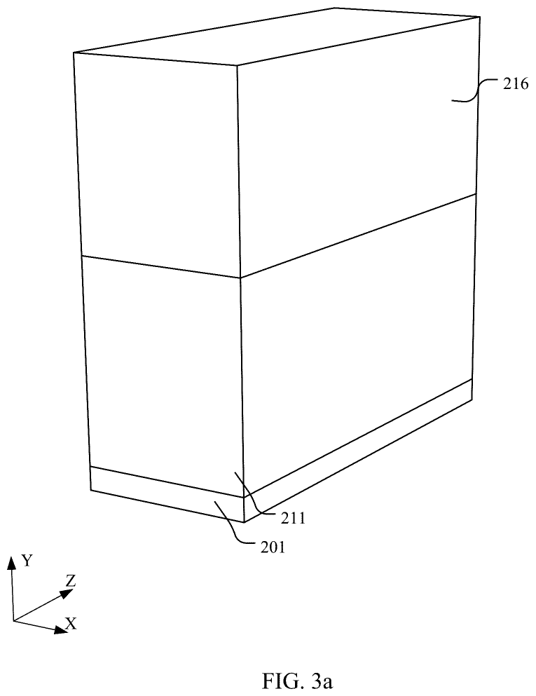

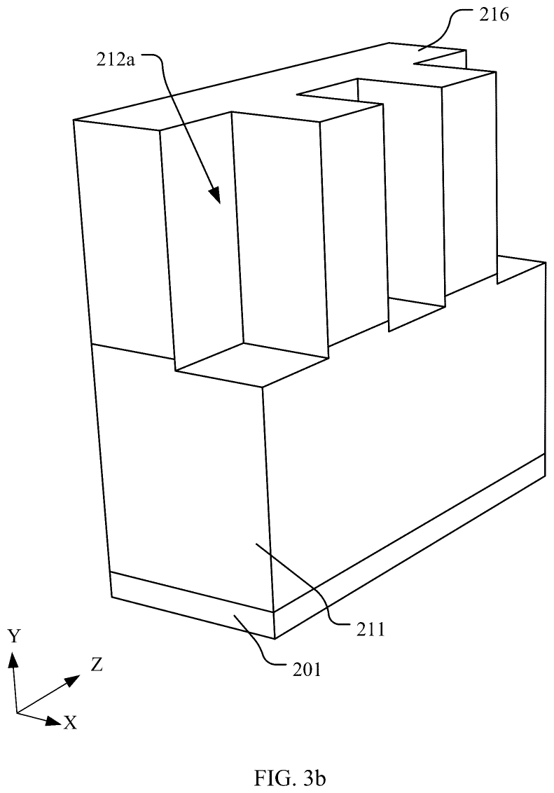

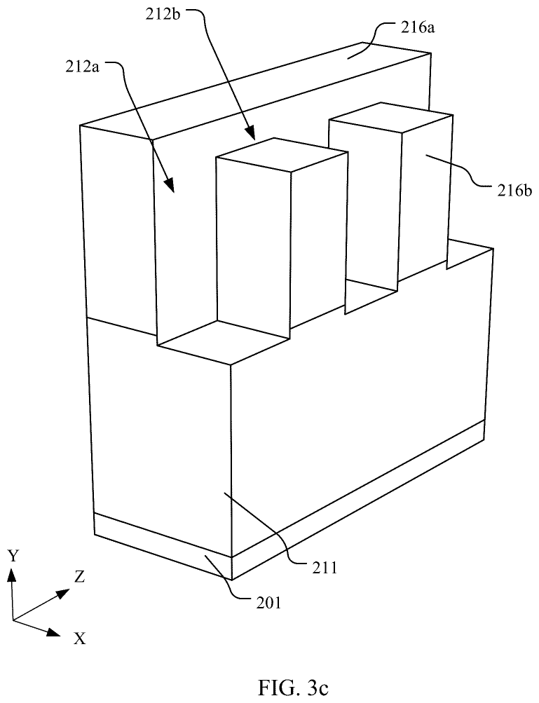

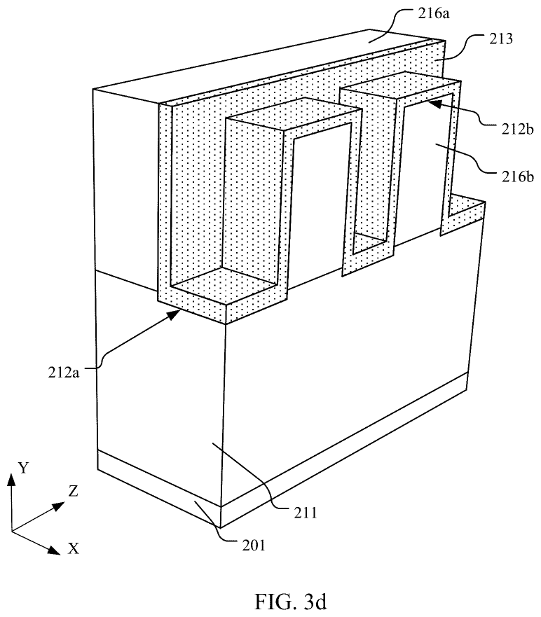

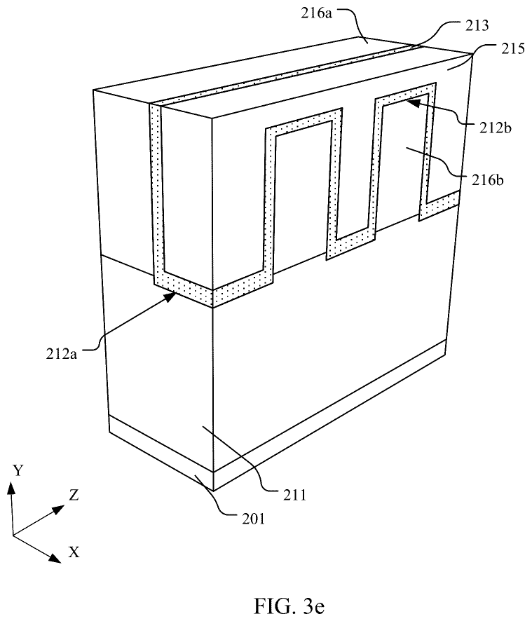

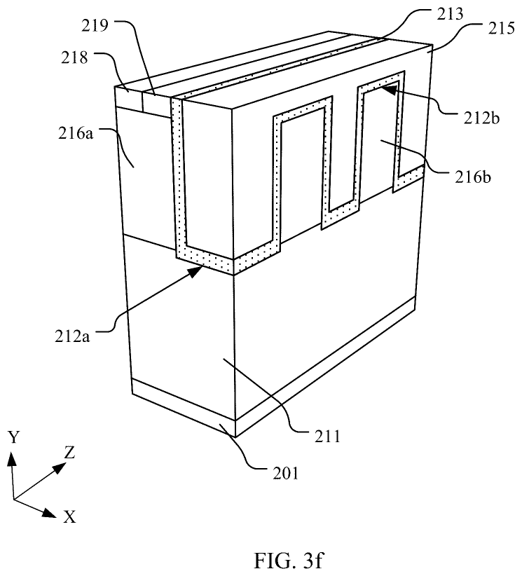

FIGS. 3a-3f schematically show the trench gate semiconductor device 20 at different stages of the manufacturing process in accordance with an embodiment of the present disclosure. The manufacturing method of the trench gate semiconductor device of the embodiments of the present disclosure is illustrated with reference to FIGS. 3a-3f.

In FIG. 3a, the epitaxial layer 211 is formed on the first surface of the substrate 201, and the body region 216 is formed in the portion of the epitaxial layer 211 which is distanced away from the substrate 201.

The epitaxial layer 211 on the first surface of the substrate 201 could be formed by any known means, like epitaxial growth. The epitaxial layer 211 has the first conductivity type and is configured as the drift region of the semiconductor device. The substrate 201 has the first conductivity type and is configured as the drain region of the semiconductor device. The doping concentration of the substrate 201 is relatively higher that the doping concentration of the epitaxial layer 211. In one embodiment, the substrate 201 is made of n-type monocrystal silicon.

After forming the epitaxial layer 211, a first ion-implantation is performed to form the body region 216 in the epitaxial layer 211. The body region 216 has the second conductivity type.

In FIG. 3b, the first trenches 212a are formed.

The first trenches 212a are formed by a photolithography process. Specifically, a first mask is formed on the epitaxial layer 211 and is patterned. Then the epitaxial layer 211 is etched through the openings of the patterned first mask to form the first trenches 212a. The first mask is removed after forming the first trenches 212a.

In FIG. 3c, the second trenches 212b are formed.

The second trenches 212b are formed by a photolithography process. Specifically, a second mask is formed on the epitaxial layer 211 and is patterned. Then the epitaxial layer 211 (mesas between the first trenches 212a) is etched through the openings of the patterned second mask to form the second trenches 212b. The second mask is removed after forming the second trenches 212b.

In one embodiment, the first trenches 212a and the second trenches 212b may be formed by a dry etching process, e.g., ion milling etching, plasma etching, reactive ion etching laser ablation, or may be formed by a wet etching process. The first mask and the second mask may be photoresist mask.

The first trenches 212a and the second trenches 212b have different depths. In the first direction, the first trenches 212a and the second trenches 212b are arranged alternately, and adjoins each other. After forming the first trenches 212a and the second trenches 212b, the portions of the body region 216 along the sidewalls of the first trenches 212a and the second trenches 212b in the first direction are defined as the first portions 216a of the body region 216, and the portions of the body region 216 between the neighboring first trenches 212a in the first direction and meanwhile under the second trenches 212b are defined as the second portions 216b of the body region 216.

In FIG. 3d, the gate dielectric layer 213 is formed.

To form the gate dielectric layer 213, a thermal oxidation process or CVD (chemical vapor deposition) may be performed. The gate dielectric layer 213 covers the inner surface of the first trenches 212a and the second trenches 212b. In some embodiments, the gate dielectric layer 213 may be silicon oxide layer or silicon nitride layer. The thermal oxidation process may include HTO (Hydrothermal oxidation) or SRO (Selective Reactive Oxidation), etc. The CVD could includes LPCVD (low pressure chemical vapor deposition) or SACVD (selected area chemical vapor deposition), etc.

In FIG. 3e, the gate electrode 215 is formed.

The gate electrode 215 is formed in the cavity shaped by the first trench 212a and the second trench 212b via any known means, like deposition process.

In FIG. 3f, the source region 219 and the contact region 218 are formed.

The contact region 218 is formed by a photography process and a second ion-implantation process. Specifically, a patterned mask is formed above the epitaxial layer 211 and the gate electrode 215. Then dopants are implanted into the body region 216 via the openings of the patterned mask by the second ion-implantation process. After forming the contact region 218, the mask is removed.

In a following step, the source region 219 is formed by a photography process and a third ion-implantation process. Specifically, a patterned mask is formed above the epitaxial layer 211 and the gate electrode 215. Then dopants are implanted into the body region 216 via the openings of the patterned mask by the third ion-implantation process. After forming the source region 219, the mask is removed.

In a following step, the interlayer dielectric layer 217 is formed atop the source region 219 and the gate electrode 215 by known means, like the deposition process. CMP (Chemical Mechanical Planarization) is performed to the semiconductor device to obtain a planar surface.

In a next step, a photography process is performed to the interlayer dielectric layer 217 to form openings. Vias may then be formed in the openings of the interlayer dielectric layer 217 to make contacts to the source region 219 and the contact region 218.

In a next step, the source electrode 222 are deposited on the top of the interlayer dielectric layer 217 to contact the source region 219 and the contact region 218 via the openings of the interlayer dielectric layer 217 or through the vias in the opening of the interlayer dielectric layer 217. Also, the drain electrode 221 are formed on the second surface of the substrate 201. The trench gate semiconductor device 20 in FIG. 2 is then formed.

In the embodiments of the present disclosure, the source electrode 222, the gate electrode 215 and the drain electrode 221 may be formed by conductive materials, like metal (e.g., copper), or alloy (e.g., aluminum alloy).

While various embodiments have been described above to illustrate the semiconductor device and its manufacturing method of the present disclosure, it should be understood that they have been presented by way of example only, and not limitation. Rather, the scope of the present disclosure is defined by the following claims and includes combinations and sub-combinations of the various features described above, as well as variations and modifications thereof, which would occur to persons skilled in the art upon reading the foregoing description.

1. A trench gate semiconductor device, comprising:
a substrate having a first surface and a second surface parallel and opposite to the first surface;
an epitaxial layer formed on the first surface of the substrate, the epitaxial layer having a first surface and a second surface parallel and opposite to the first surface of the epitaxial layer;
at least one first trench gate structure formed in the epitaxial layer, the at least one first trench gate structure vertically extending from the first surface of the epitaxial layer, and having a first depth; and
at least one second trench gate structure formed in the epitaxial layer, the at least one second trench gate structure vertically extending from the first surface of the epitaxial layer, and having a second depth, wherein the first depth is greater than the second depth; wherein
the at least one first trench gate structure and the at least one second trench gate structure are arranged alternately in a line along a first direction, and the neighboring first trench gate structure and second trench gate structure adjoins each other.

2. The trench gate semiconductor device of claim 1, further comprising:
a body region formed in the epitaxial layer, the body region having first portions and second portions, wherein the first portions of the body region are formed alongside the sidewalls of the at least one first trench gate structure and the at least one second trench gate structure in the first direction, and each one of the second portions of the body region is formed between the associated neighboring first trench gate structures and under the associated second trench gate structure which is between the associated neighboring first trench gate structures, and wherein the first portions and the second portions of the body region adjoins each other to form the body region.

3. The trench gate semiconductor device of claim 2, further comprising:
a source region formed in the body region, the source region having a first sidewall and a second sidewall, wherein the first sidewall of the source region adjoins the sidewalls of the at least one first trench gate structure and the at least one second trench gate structure along the first direction.

4. The trench gate semiconductor device of claim 3, further comprising:
a contact region formed in the body region, the contact region having a first sidewall and a second sidewall, wherein the first sidewall of the contact region adjoins the second sidewall of the source region.

5. The trench gate semiconductor device of claim 3, wherein the source region has a depth smaller than the second depth of the at least second trench gate structure.

6. The trench gate semiconductor device of claim 1, wherein:
in the first direction, each one of the at least one first trench gate structure has a length z1, each one of the at least one second trench gate structure has a length z2;
in a second direction normal to the first direction and parallel to the first surface of the epitaxial layer, both of the at least one first trench gate structure and the at least one second trench gate structure have a length x; and
in a third direction normal to the first surface of the epitaxial layer, each one of the at least one first trench gate structure has a length y1, and each one of the at least one second trench gate structure has a length y2; and wherein
$$0 < z 2 < \frac{2 * ( y 1 - y 2 ) * x}{2 * ( y 1 - y 2 ) - x} .$$

7. The trench gate semiconductor device of claim 1, wherein:
each one of the at least one first trench gate structure comprises a first trench;
each one of the at least one second trench gate structure comprises a second trench; and
the first trench and the second trench are connected to form a cavity to accommodate a gate electrode, and wherein a gate dielectric layer covers an inner surface of the first trench and the second trench for insulating the gate electrode from the first trench and the second trench.

8. A trench gate semiconductor device, comprising:
a substrate having a first surface and a second surface parallel and opposite to the first surface;
an epitaxial layer formed on the first surface of the substrate, the epitaxial layer having a first surface and a second surface parallel and opposite to the first surface of the epitaxial layer;
a first trench gate structure formed in the epitaxial layer, the first trench gate structure vertically extending from the first surface of the epitaxial layer, and having a first depth; and
a second trench gate structure formed in the epitaxial layer, the second trench gate structure vertically extending from the first surface of the epitaxial layer, and having a second depth, wherein the first depth is greater than the second depth; wherein
the first trench gate structure and the second trench gate structure are arranged in a line along a first direction and adjoins each other.

9. The trench gate semiconductor device of claim 8, further comprising:
a body region formed in the epitaxial layer, the body region having first portions and a second portion, wherein the first portions of the body region are formed alongside the sidewalls of the first trench gate structure and the second trench gate structure in the first direction, and the second portion of the body region is formed under the second trench gate structure, and wherein the first portions and the second portion of the body region adjoins each other to form the body region.

10. The trench gate semiconductor device of claim 9, further comprising:
a source region formed in the body region, the source region having a first sidewall and a second sidewall, wherein the first sidewall of the source region adjoins the sidewalls of the first trench gate structure and the second trench gate structure along the first direction.

11. The trench gate semiconductor device of claim 10, further comprising:
a contact region formed in the body region, the contact region having a first sidewall and a second sidewall, wherein the first sidewall of the contact region adjoins the second sidewall of the source region.

12. The trench gate semiconductor device of claim 10, wherein the depth of the source region is smaller than the second depth of the second trench gate structure.

13. The trench gate semiconductor device of claim 8, wherein:
in the first direction, the first trench gate structure has a length z1, the second trench gate structure has a length z2;
in a second direction normal to the first direction and parallel to the first surface of the epitaxial layer, both of the first trench gate structure and the second trench gate structure have a length x; and
in a third direction normal to the first surface of the epitaxial layer, the first trench gate structure has a length y1, and the second trench gate structure has a length y2; and wherein
$$0 < z 2 < \frac{2 * ( y 1 - y 2 ) * x}{2 * ( y 1 - y 2 ) - x} .$$

14. The trench gate semiconductor device of claim 8, wherein:
the first trench gate structure comprises a first trench;
the second trench gate structure comprises a second trench; and
the first trench and the second trench are connected to form a cavity to accommodate a gate electrode, and wherein a gate dielectric layer covers an inner surface of the first trench and the second trench for insulating the gate electrode from the first trench and the second trench.

15. A manufacturing method of a trench gate semiconductor device, comprising:
forming a substrate having a first surface and a second surface parallel and opposite to the first surface;
forming an epitaxial layer on the first surface of the substrate having a first surface and a second surface parallel and opposite to the first surface of the epitaxial layer;
forming a body region in the epitaxial layer;
forming at least one first trench gate structure and at least one second trench gate structure in the body region, wherein the at least one first trench gate structure and the at least one second trench gate structure are arranged alternately in a line along a first direction and are connected to each other, wherein the at least one first trench gate structure has a first depth and the at least one second trench gate structure has a second depth, and wherein the first depth is greater than the second depth and a depth of the body region;
forming a source region in the body region, wherein the source region has a sidewall adjoins the at least one first trench gate structure and the at least one second trench gate structure along the first direction.

16. The manufacturing method of the trench gate semiconductor device of claim 15, wherein forming the at least one first trench gate structure and the at least one second trench gate structure comprises:
forming at least one first trench and at least one second trench in the body region, wherein the at least one first trench and the at least one second trench are arranged alternately in a line along a first direction and are connected to each other;
forming a gate dielectric layer to cover an inner surface of a cavity formed by the at least one first trench and the at least one second trench; and
forming a gate electrode to fill the cavity formed by the at least one first trench and the at least second trench.

17. The manufacturing method of the trench gate semiconductor device of claim 15, further comprising:
forming a contact region in the body region, wherein the contact region adjoins the other sidewall of the source region.

18. The manufacturing method of the trench gate semiconductor device of claim 15, wherein the source region has a depth smaller than the second depth of the at least one second trench gate structure.

19. The manufacturing method of the trench gate semiconductor device of claim 15, wherein:
in the first direction, each one of the at least one first trench gate structure has a length z1, each one of the at least one second trench gate structure has a length z2;
in a second direction normal to the first direction and parallel to the first surface of the epitaxial layer, both of the at least one first trench gate structure and the at least one second trench gate structure have a length x;
in a third direction normal to the first surface of the epitaxial layer, each one of the at least one first trench gate structure has a length y1, each one of the at least one second trench gate structure has a length y2; and wherein
$$0 < z 2 < \frac{2 * ( y 1 - y 2 ) * x}{2 * ( y 1 - y 2 ) - x} .$$

20. The manufacturing method of the trench gate semiconductor device of claim 15, wherein:
the substrate, the epitaxial layer and the source region have a first conductivity type; and
the body region has a second conductivity type.
